(19) United States
(12) Patent Application Publication
(10) Pub. No.: US 2018/0217421 A1
(43) Pub. Date: Aug. 2, 2018

(54) DISPLAY SUBSTRATE AND MANUFACTURING METHOD THEREOF AND DISPLAY DEVICE

(71) Applicant: Boe Technology Group Co., Ltd., Beijing (CN)

(72) Inventors: Shantao Chen, Beijing (CN); Huijuan Zhang, Beijing (CN); Yidong Guo, Beijing (CN)

(21) Appl. No.: 15/322,547

(22) PCT Filed: May 23, 2016
(86) PCT No.: PCT/CN2016/082986

§ 371 Date: Dec. 28, 2016

(30) Foreign Application Priority Data
Jan. 4, 2016 (CN) 201610004255.4
Mar. 8, 2016 (CN) 201610130513.3

(51) Int. Cl. G02F 1/1337; G02F 1/1368; G02F 1/1333; H01L 27/12

(52) U.S. Cl. CPC G02F 1/1337; G02F 1/1368; G02F 2201/123; H01L 27/1214; G02F 2001/133357; G02F 1/133371

(57) ABSTRACT

Embodiments of the present disclosure provide a display substrate and manufacturing method thereof and a display device. The method of manufacturing the display substrate comprises: forming a pattern including an active layer on a base substrate using an amorphous silicon material, the active layer including at least one step region having a film thickness greater than a film thickness of other regions of the active layer; crystallizing the amorphous silicon material in the active layer into a polysilicon material.

### FIELD

The present disclosure relates to the field of liquid crystal display technology, and particularly to a display substrate and manufacturing method thereof and a display device.

### BACKGROUND

An active matrix type display device is a display device which uses a thin film transistor (TFT) for pixel display driving, which has a lot of advantages including light weight and thin, low power consumption, low radiation, low cost and so on, and is the most leading display technology. The active matrix type display devices all include a TFT array substrate. Moreover, according to different materials that form the TFT active layer, the TFT array substrates can be divided into many types such as amorphous silicon (a-Si: H), low temperature polysilicon (referred to as LTPS for short), high temperature polysilicon (referred to as HTPS for short), oxide semiconductor and the like.

The low temperature polysilicon (referred to as LTPS for short) thin film can produce a relatively high driving current due to its characteristics such as regular atomic arrangement, high carrier mobility, and so on, which can accelerate the reaction time of liquid crystal molecules, reduce the volume of thin film transistor and increase the transmissive area in a pixel unit, such that the display device has higher brightness, resolution and aperture ratio. Thus, it is widely used in the thin film transistor manufacturing process. However, since the amorphous silicon structure is unstable, it is necessary to crystallize the amorphous silicon material at the time of preparing the thin film transistor. The disadvantages of the conventional crystallization technology lie in limited size of crystal grains after crystallization and poor uniformity of product performances.

### SUMMARY

Embodiments of the present disclosure provide a display substrate and manufacturing method thereof and a display device, which may solve the problems that the formed crystal grains are limited in size and the product uniformity is poor in the prior art.

Embodiments of the present disclosure provide a method of manufacturing a display substrate. The method comprises: forming a pattern including an active layer on a base substrate using an amorphous silicon material, the active layer including at least one step region having a film thickness greater than a film thickness of other regions of the active layer; crystallizing the amorphous silicon material in the active layer into a polysilicon material.

In the method provided by embodiments of the present disclosure, the active layer formed from the amorphous silicon material includes at least one step region having a film thickness greater than the film thickness of other regions of the active layer. During the crystallization process, by means of the energy density difference between regions with different film thicknesses, the amorphous silicon material in the region with greater film thickness is kept in an incompletely molten state while the amorphous silicon material in other regions of the active layer is in a completely molten state, and the active layer is then crystallized using the amorphous silicon portion in the incompletely molten state as a nucleation center of the crystallization process. In the subsequent crystallization process, due to the presence of a crystal nucleus, crystal grains of large size can be formed, providing product uniformity.

In an example implementation, in the above method provided by embodiments of the present disclosure, forming a pattern including an active layer on a base substrate using an amorphous silicon material, the active layer including at least one step region, comprises: forming an amorphous silicon material layer on the base substrate; removing hydrogen from the amorphous silicon material using annealing process; and forming a pattern including an active layer on the base substrate using a halftone mask, the active layer including a plurality of regularly arranged step regions.

After the amorphous silicon material layer is formed on the base substrate, hydrogen is removed from the amorphous silicon material by the annealing process so that the hydrogen content in the amorphous silicon material is decreased to prevent occurrence of the hydrogen decrepitation phenomenon. Moreover, when the plurality of step regions in the active layer are regularly arranged, regularly arranged crystal nuclei can be formed, which is advantageous to further improvement in product uniformity.

In an example implementation, in the above method provided by embodiments of the present disclosure, crystallizing the amorphous silicon material in the active layer into a polysilicon material comprises: irradiating the active layer with laser light to crystallize the amorphous silicon material in the active layer into a polysilicon material.

In an example implementation, in the above method provided by embodiments of the present disclosure, said irradiating the active layer with laser light to crystallize the amorphous silicon material in the active layer into a polysilicon material comprises: irradiating the active layer with excimer laser light to crystallize the amorphous silicon material in the active layer into a polysilicon material.

In an example implementation, in the above method provided by embodiments of the present disclosure, irradiating the active layer with excimer laser light to crystallize the amorphous silicon material in the active layer into a polysilicon material comprises: irradiating the active layer with excimer laser light so that an amorphous silicon material in a step region of the active layer exhibits an incompletely molten state and amorphous silicon materials in regions other than the step region exhibit a completely molten state, and after crystallization, forming a polycrystal material using the amorphous silicon material in an incompletely molten state in the step region as a crystal nucleus.

When the active layer is crystallized by using the incompletely molten material in the step region as a crystal nucleus, the sizes of the crystalized polysilicon crystal grains can be effectively increased due to the presence of the crystal nucleus.

In an example implementation, in the above method provided by embodiments of the present disclosure, prior to forming a pattern including an active layer on a base substrate, the method further comprises: forming a buffer layer on the base substrate, the buffer layer being located between the base substrate and the active layer.

By disposing a buffer layer between the base substrate and the active layer, it is possible to prevent the impurities contained in the base substrate from diffusing into the active layer of the thin film transistor in the subsequent process, and prevent impacting on the characteristics such as the threshold voltage and the leakage current of the thin film transistor. Meanwhile, since the active layer uses a low temperature polysilicon material while the low temperature polysilicon is usually crystallized by excimer laser annealing process, the buffer layer can further play the role of preventing the diffusion of impurities resulting from the excimer laser annealing, which is advantageous to further improvement in the quality of the thin film transistor formed by low temperature polysilicon.

In an example implementation, the above method provided by embodiments of the present disclosure further comprises: forming a source/drain doped region in the active layer by ion injection.

By injecting ions in the active layer, the carrier concentration in the active layer is increased, thereby facilitating improvement in the characteristics of the thin film transistor.

In an example implementation, in the above method provided by embodiments of the present disclosure, prior to performing ion injection on the active layer, the method further comprises: forming a gate insulating layer on a substrate including the active layer; and forming a pattern including a gate on a substrate including the gate insulating layer.

In an example implementation, the above method provided by embodiments of the present disclosure further comprises: irradiating the active layer with laser light from a side of the base substrate facing away from the active layer to activate ions of the source/drain doped region.

By irradiating the active layer with laser light, ions in the source/drain doped region are activated, which is advantageous to improvement in the characteristics of the thin film transistor.

In an example implementation, the above method provided by embodiments of the present disclosure further comprises: irradiating the active layer with laser light to activate ions of the source/drain doped region; forming a gate insulating layer over the active layer; and forming a gate over the gate insulating layer.

The method may further comprise irradiating the active layer with laser light such that ions in the source/drain doped region are activated so as to improve the characteristics of the thin film transistor. The gate insulating layer and the gate are then formed successively over the active layer, for constructing a complete thin film transistor structure.

In an example implementation, in the above method provided by embodiments of the present disclosure, the laser light is excimer laser light.

In an example implementation, the above method provided by embodiments of the present disclosure further comprises: forming a passivation layer over the gate, and a first via hole and a second via hole penetrating through the gate insulating layer and the passivation layer; forming a source and a drain over the passivation layer, wherein the source is electrically connected to the active layer via the first via hole, and the drain is electrically connected to the active layer via the second via hole; forming a planarization layer over the source and the drain, and a third via hole penetrating through the planarization layer; forming a pixel electrode over the planarization layer and electrically connecting the pixel electrode to the drain via the third via hole.

In an example implementation, the above method provided by embodiments of the present disclosure further comprises forming an alignment film layer over the pixel electrode.

By forming an alignment film layer over the pixel electrode, a certain orientation of corresponding liquid crystal molecules is enabled, thereby controlling the passage of light.

In an example implementation, in the above method provided by embodiments of the present disclosure, a difference in thickness between the step region of the active layer and other regions of the active layer is 300 to 500 Å.

On the basis of the same inventive concept, embodiments of the present disclosure further provide a display substrate which is manufactured by the above method.

On the basis of the same inventive concept, embodiments of the present disclosure further provide a display device comprising the display substrate described above.

### BRIEF DESCRIPTION OF DRAWINGS

FIG. 1 is a flow chart illustrating a method of manufacturing a display substrate provided by embodiments of the present disclosure;

FIG. 2 is a flow chart illustrating a method of manufacturing a display substrate provided by embodiments of the present disclosure;

FIGS. 3-14 are schematic views illustrating respective steps of the method of manufacturing a display substrate provided by embodiments of the present disclosure.

### DETAILED DESCRIPTION

Embodiments of the present disclosure provide a display substrate and manufacturing method thereof and a display device, which may solve the problems that the crystal grains formed by laser crystallization are limited in size and the product uniformity is poor in the prior art.

The technical solutions in embodiments of the present disclosure will be clearly and completely described below with reference to the drawings in embodiments of the present disclosure. Apparently, the described embodiments are just a part of the embodiments of the present disclosure rather than all of them.

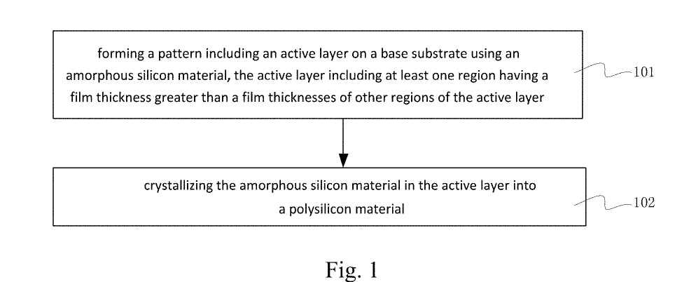

Embodiments of the present disclosure provide a method of manufacturing a display substrate. Referring to FIG. 1, the method comprises: in step 101, forming a pattern including an active layer on a base substrate using an amorphous silicon material, the active layer including at least one step region having a film thickness greater than a film thicknesses of other regions of the active layer; in step 102, crystallizing the amorphous silicon material in the active layer into a polysilicon material.

In the method provided by embodiments of the present disclosure, the active layer formed from the amorphous silicon material includes at least one step region having a film thickness greater than the film thickness of other regions of the active layer. During the crystallization process, by means of the energy density difference between regions with different film thicknesses, the amorphous silicon material in the region with greater film thickness is kept in an incompletely molten state while the amorphous silicon material in other regions of the active layer is in a completely molten state, and the active layer is then crystallized using the amorphous silicon portion in the incompletely molten state as a nucleation center of the crystallization process. In the subsequent crystallization process, due to the presence of a crystal nucleus, crystal grains of large size can be formed, providing product uniformity.

In the process of manufacturing the display substrate, said forming a pattern including an active layer on a base substrate using an amorphous silicon material, the active layer including at least one step region, comprises: forming an amorphous silicon material layer on the base substrate; removing hydrogen from the amorphous silicon material using an annealing process; and forming a pattern including an active layer on the base substrate using a halftone mask, the active layer including a plurality of regularly arranged step regions.

After the amorphous silicon material layer is formed on the base substrate, the amorphous silicon material is subjected to dehydrogenation treatment by annealing process so that the hydrogen content in the amorphous silicon material is decreased to less than 2%, thereby preventing occurrence of the hydrogen decrepitation phenomenon. Moreover, when the plurality of step regions in the active layer are regularly arranged, regularly arranged crystal nuclei can be formed, which is advantageous to further improvement in product uniformity.

Further, crystallizing the amorphous silicon material in the active layer into a polysilicon material comprises: irradiating the active layer with laser light to crystallize the amorphous silicon material in the active layer into a polysilicon material. Of course, the active layer can also be crystallized in other manners such as solid phase crystallization and metal induced crystallization.

Further, irradiating the active layer with laser light to crystallize the amorphous silicon material in the active layer into a polysilicon material can specifically be achieved by irradiating the active layer with excimer laser light such that the amorphous silicon material in the active layer is crystallized into a polysilicon material.

Further, the active layer is irradiated with excimer laser light such that the amorphous silicon material in the step region of the active layer exhibits an incompletely molten state and the amorphous silicon material in the regions other than the step region exhibits a completely molten state. After crystallization, a polycrystal material which uses the amorphous silicon material in an incompletely molten state in the step region as a crystal nucleus is formed.

When the active layer is crystallized by using the incompletely molten material in the step region as a crystal nucleus, the sizes of the crystal grains can be effectively increased due to the presence of the crystal nucleus.

Specifically, it can be obtained from experiments that the difference between the film thickness of the step region and the film thickness of other regions of the active layer would not affect the sizes of the crystallized crystal grains, but would influence the realization of the process effect. Moreover, as the thickness difference increases, the influence on the process effect becomes greater. Thus, the reference range of the thickness difference is 300 to 500 Å. Moreover, the process parameters of laser crystallization are also related to the thickness difference. For example, when the thickness difference is 450 Å, the corresponding energy density is 400 mJ/cm². This parameter is slightly lower than the normal process parameter when the step region is not disposed.

Furthermore, the film thickness of the step region is generally around 500 to 800 Å, and the thickness of other regions is generally 300 to 600 Å. Specifically, the step region may be a circular raised region having a diameter of 500 to 1000 nm and a distribution interval of 1000 to 2000 nm.

Further, prior to forming a pattern including an active layer on a base substrate, the method further comprises forming a buffer layer over the base substrate, the buffer layer being located between the base substrate and the active layer.

By disposing a buffer layer between the base substrate and the active layer, it is possible to prevent the impurities contained in the base substrate from diffusing into the active layer of the thin film transistor in the subsequent process, and prevent impacting on the characteristics such as the threshold voltage and the leakage current of the thin film transistor. Meanwhile, since the active layer uses a low temperature polysilicon material while the low temperature polysilicon is usually crystallized by excimer laser annealing method, the buffer layer can further play the role of preventing the diffusion of impurities resulting from the excimer laser annealing, which is advantageous to further improvement in the quality of the thin film transistor formed by low temperature polysilicon.

Further, the method further comprises forming a source/drain doped region in the active layer by ion injection.

By injecting ions in the active layer, the carrier concentration in the active layer is increased, thereby facilitating improvement in the characteristics of the thin film transistor.

Further, prior to performing ion injection on the active layer, the method further comprises: forming a gate insulating layer on a substrate including the active layer; forming a pattern including a gate on a substrate including the gate insulating layer.

For example, by using chemical vapor deposition method, a gate insulating layer is formed on a substrate with the active layer formed. The deposition temperature is generally kept below 500° C. The thickness of the gate insulation layer can be 100 to 600 Å. It is also possible to select a suitable thickness based on specific process requirements. As another example, the gate insulating layer may be monolayer silicon oxide, silicon to nitride, or a stack of both. When the monolayer silicon oxide is used, the thickness of the gate insulating layer is generally 400 to 600 Å, and when the monolayer silicon nitride is used, the thickness of the gate insulating layer is generally 100 to 400 Å.

In the above step, after the gate insulating layer and the gate are formed, the ion injection is performed using the gate as a mask. The specific process may comprise first irradiating the active layer with laser light such that ions in the source/drain doped region are activated so as to improve the characteristics of the thin film transistor, then forming the gate insulating layer and the gate successively over the active layer, for constructing a complete thin film transistor structure. The process may specifically comprise: irradiating the active layer with laser light from a side of the base substrate facing away from the active layer to activate ions in the source/drain doped region. In particular, the excimer laser light can be used to irradiate the active layer.

By irradiating the active layer with laser light, ions in the source/drain doped region are activated, which is advantageous to improvement in the characteristics of the thin film transistor.

Further, in order to construct a complete display substrate, the substrate should further include a source, a drain, a pixel electrode, a passivation layer for insulating the gate from the source/drain, and a planarization layer provided between the source/drain and the pixel electrode. The steps of forming these structures in embodiments of the present disclosure comprise: forming a passivation layer over the gate, and a first via hole and a second via hole penetrating through the gate insulating layer and the passivation layer; forming a source and a drain over the passivation layer, wherein the source is electrically connected to the active layer via the first via hole, and the drain is electrically connected to the active layer via the second via hole; forming a planarization layer over the source and drain, and a third via hole penetrating through the planarization layer; forming a pixel electrode over the planarization layer, and electrically connecting the pixel electrode to the drain via the third via hole.

Further, to enable a certain orientation of the liquid crystal molecules corresponding to the display substrate, the display substrate is further provided with an alignment film layer. The method of manufacturing the display substrate further comprises forming an alignment film layer over the pixel electrode.

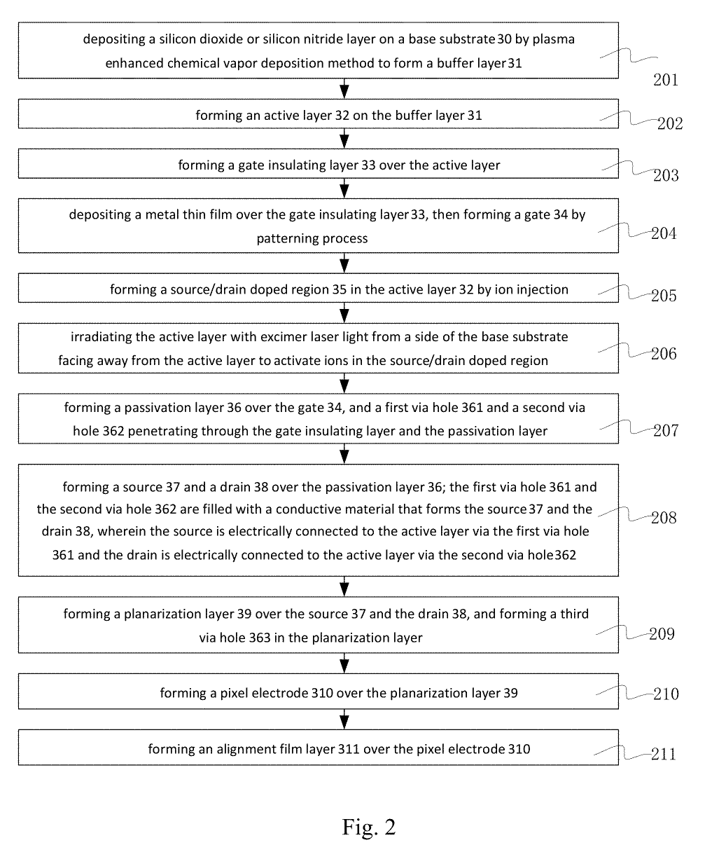

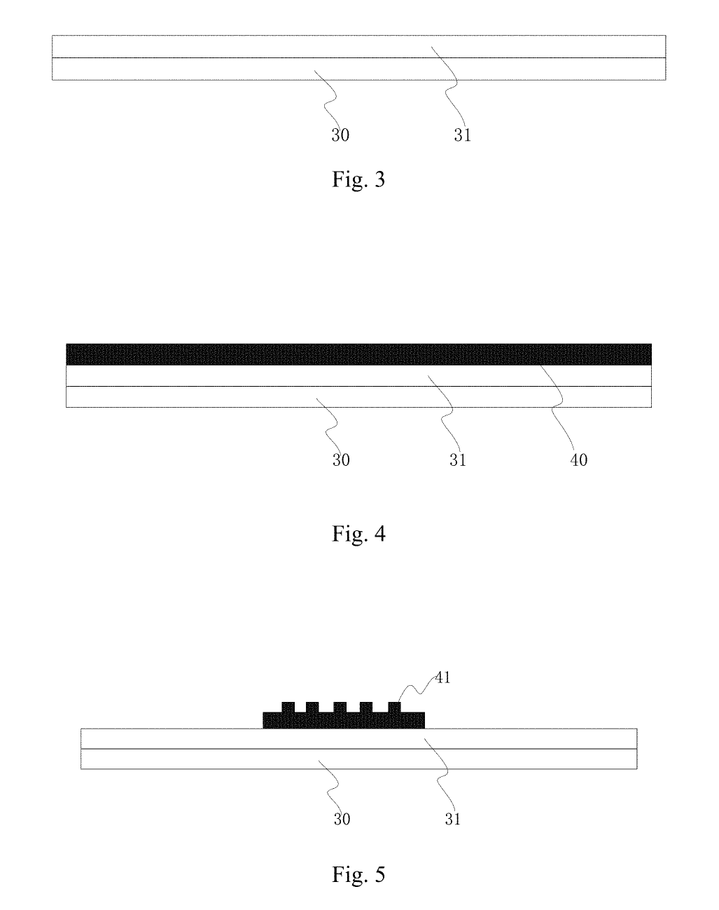

To make the objective, technical solutions and advantages of the present disclosure clearer, it is described below step by step in detail with reference to the drawings and specific embodiments. Referring to FIG. 2, at step 201, as shown in FIG. 3, a silicon dioxide or silicon nitride layer is deposited on a base substrate 30 by plasma enhanced chemical vapor deposition method to form a buffer layer 31.

In this embodiment, the buffer layer 31 is configured to prevent the impurities contained in the base substrate from diffusing into the active layer of the thin film transistor in the subsequent process and prevent impacting on the characteristics such as the threshold voltage and the leakage current of the thin film transistor. Meanwhile, since the active layer uses a low temperature polysilicon material, and the low temperature polysilicon is usually treated by excimer laser annealing process, disposing the buffer layer 31 can also prevent the diffusion of impurities resulting from excimer laser annealing, thereby improving the quality of the thin film transistor formed by low temperature polysilicon.

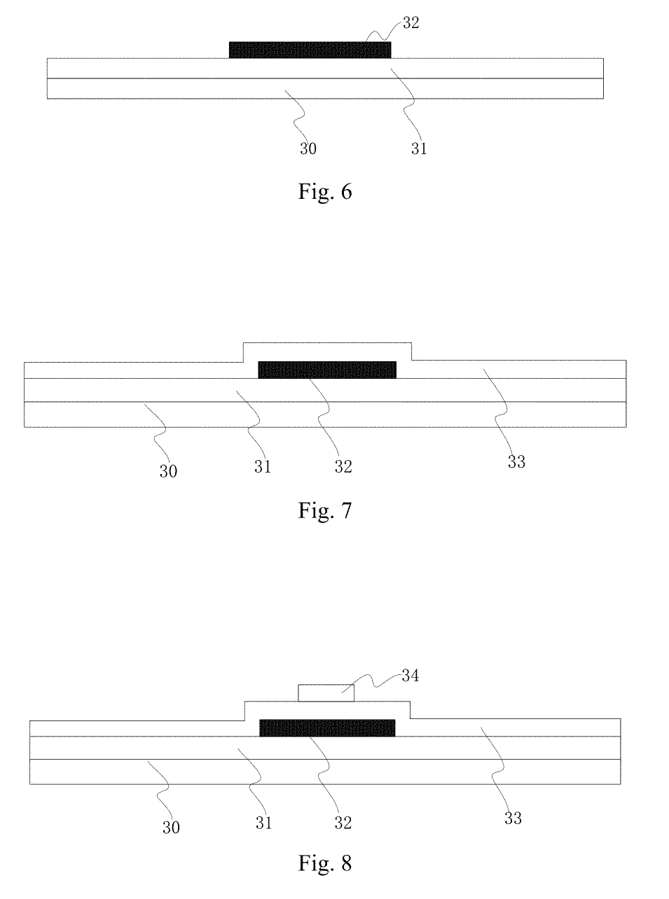

At step 202, an active layer 32 is formed on the buffer layer 31. This step specifically comprises: referring to FIG. 4, forming an amorphous silicon material layer 40 on the base substrate with the buffer layer 31; removing hydrogen from the amorphous silicon material using annealing process such that the hydrogen content in the amorphous silicon material is decreased to less than 2%, so as to prevent occurrence of the hydrogen decrepitation phenomenon; referring to FIG. 5, forming a pattern including an active layer on the base substrate by using a halftone mask, the active layer including a plurality of regularly arranged step regions 41; referring to FIG. 6, irradiating the active layer with excimer laser light such that the amorphous silicon material in the active layer is crystallized into a polysilicon material to form a surface-flat active layer 32.

At step 203, referring to FIG. 7, a gate insulating layer 33 is formed over the active layer. This step specifically comprises: by using chemical vapor deposition method, forming a gate insulating layer on a substrate with the active layer formed. The deposition temperature is kept below 500° C. A transparent insulating material is deposited over the active layer to form a gate insulating layer. The thickness of the gate insulation layer is generally 100 to 600 Å. It is also possible to select a suitable thickness based on specific process requirements. The gate insulating layer may be monolayer silicon oxide, silicon nitride, or a stack of both. When the monolayer silicon oxide is used, the thickness of the gate insulating layer is generally 400 to 600 Å, and when the monolayer silicon nitride is used, the thickness of the gate insulating layer is generally 100 to 400 Å.

At step 204, referring to FIG. 8, a metal film is deposited over the gate insulating layer 33. Then a gate 34 is formed by patterning process. The steps specifically comprise: forming (e.g. by sputtering or coating), on the gate insulating layer, a metal film for forming a gate, coating a layer of photoresist on the metal film, exposing the photoresist using a mask provided with a pattern of the gate, and forming a pattern of the gate by development and etching. In the manufacturing method of an display substrate in this embodiment, the preparation process of forming film layers by patterning process is the same as the above process, which will not be described later in detail.

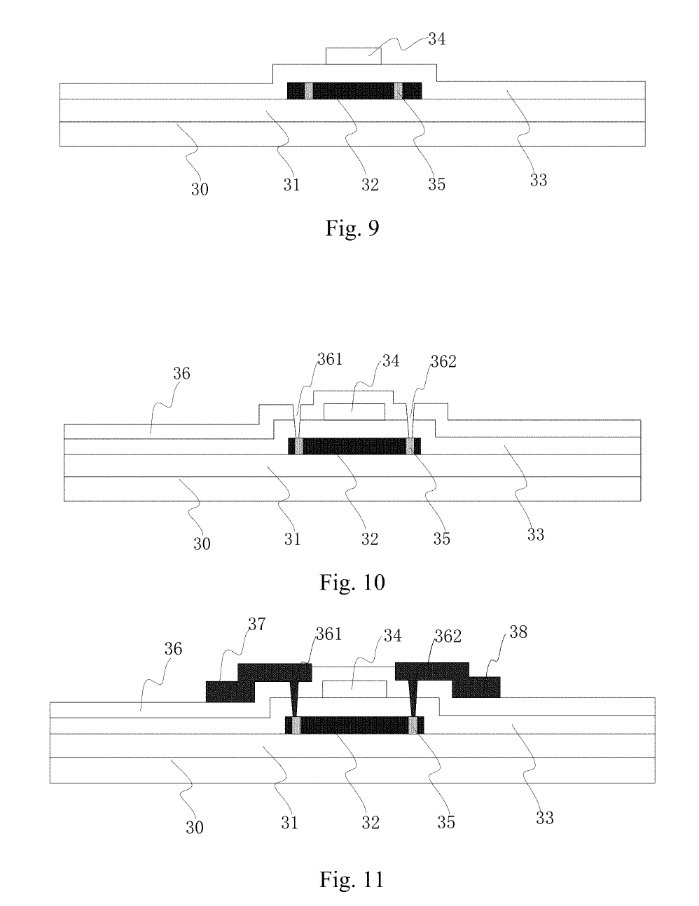

At step 205, referring to FIG. 9, a source/drain doped region 35 is formed in the active layer 32 by ion injection.

In this embodiment, the ions in the ion injection procedure may be one or more of B ions, P ions, As ions and PHx ions. Specifically, the ion injection may be implemented by ion injection with a mass analyzer, ion cloud injection without a mass analyzer, plasma injection or solid-state diffusive injection, and the like, and the injection may be performed dependent on practical needs.

At step 206, the active layer is irradiated with excimer laser light from a side of the base substrate facing away from the active layer to activate ions in the source/drain doped region.

At step 207, referring to FIG. 10, a passivation layer 36 is formed over the gate 34, and a first via hole 361 and a second via hole 362 penetrating through the gate insulating layer and the passivation layer are formed.

At step 208, referring to FIG. 11, a source 37 and a drain 38 are formed over the passivation layer 36. The first via hole 361 and the second via hole 362 are filled with a conductive material that forms the source 37 and the drain 38, wherein the source is electrically connected to the active layer via the first via hole 361 and the drain is electrically connected to the active layer via the second via hole 362.

When the source and the drain are formed by patterning process, the first and second via holes may be formed by wet etching or dry etching, and the source 37 and the drain 38 may be formed of a conductive material such as metal, metal alloy, and the like.

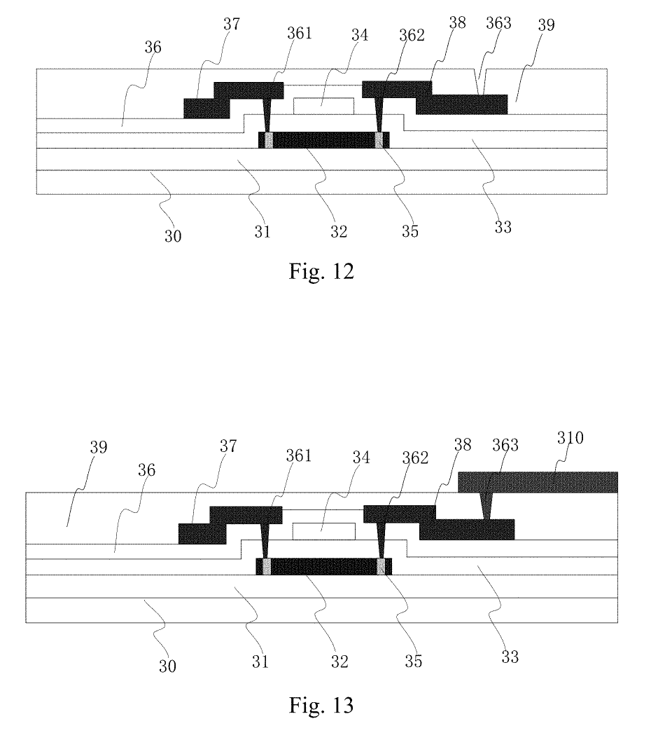

At step 209, referring to FIG. 12, a planarization layer 39 is formed over the source 37 and the drain 38, and a third via hole 363 is formed in the planarization layer.

At step 210, referring to FIG. 13, a pixel electrode 310 is formed over the planarization layer 39. This step specifically comprises: depositing an indium tin oxide (ITO) transparent conductive film on the planarization layer 39 by magnetron sputtering method, applying a photoresist and performing exposure and development, performing wet etching and peeling to form a pattern of the pixel electrode 310. The third via hole 363 is filled with a conductive material for forming the pixel electrode, and the pixel electrode 310 is electrically connected to the drain via the third via hole 363.

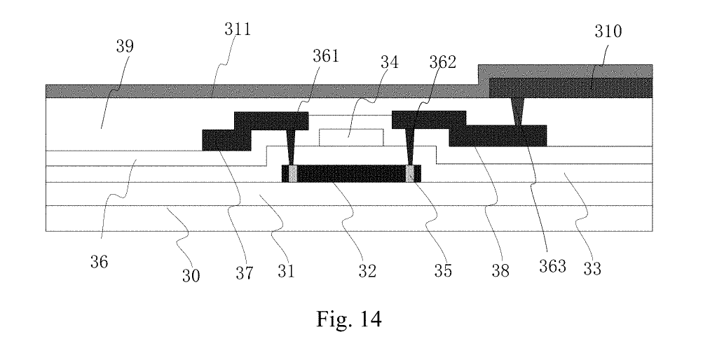

At step 211, referring to FIG. 14, an alignment film layer 311 is formed over the pixel electrode 310. The alignment film layer 311 may be formed by transfer printing using an alignment film printing plate, and may also be formed by ink jet printing. In practice, those skilled in the art can select a specific process based on needs.

In the above steps, after the gate insulating layer and the gate are formed, the ion injection is performed using the gate as a mask. The specific process may comprise first irradiating the active layer with laser light such that ions in the source/drain doped region are activated so as to improve the characteristics of the thin film transistor; forming the gate insulating layer and the gate successively over the active layer, for constructing a complete thin film transistor structure. In addition, the amorphous silicon can also be doped in a predetermined source/drain doped region prior to crystallization of the amorphous silicon, and then irradiated once by excimer laser light to realize crystallization of the amorphous silicon of the active layer and activation of ions in the source/drain doped region at the same time, thereby reducing the process procedures and reducing the production cost.

On the basis of the same inventive concept, embodiments of the present disclosure further provide a display substrate which is manufactured by the aforesaid method.

On the basis of the same inventive concept, embodiments of the present disclosure further provide a display device comprising the display substrate described above.

Apparently, those skilled in the art can make various modifications and variations to the present disclosure without departing from the spirit and scope thereof. In this way, if these modifications and variations to the present disclosure fall within the scope of the claims of the present disclosure and equivalent technologies thereof, the present disclosure also intends to encompass these modifications and variations.

1. A method of manufacturing a display substrate, comprising:
forming a pattern including an active layer on a base substrate using an amorphous silicon material, the active layer including at least one step region having a film thickness greater than a film thickness of other regions of the active layer;
crystallizing the amorphous silicon material in the active layer into a polysilicon material.

2. The method according to claim 1, wherein forming a pattern including an active layer on a base substrate using an amorphous silicon material, the active layer including at least one step region, comprises:
forming an amorphous silicon material layer on the base substrate;
removing hydrogen from the amorphous silicon material using annealing process;
forming a pattern including an active layer on the base substrate using a halftone mask, the active layer including a plurality of regularly arranged step regions.

3. The method according to claim 1, wherein crystallizing the amorphous silicon material in the active layer into a polysilicon material comprises:
irradiating the active layer with laser light to crystallize the amorphous silicon material in the active layer into a polysilicon material.

4. The method according to claim 3, wherein said irradiating the active layer with laser light to crystallize the amorphous silicon material in the active layer into a polysilicon material comprises:
irradiating the active layer with excimer laser light to crystallize the amorphous silicon material in the active layer into a polysilicon material.

5. The method according to claim 4, wherein irradiating the active layer with excimer laser light to crystallize the amorphous silicon material in the active layer into a polysilicon material comprises:
irradiating the active layer with excimer laser light so that an amorphous silicon material in a step region of the active layer exhibits an incompletely molten state and amorphous silicon materials in regions other than the step region exhibit a completely molten state, after crystallization, forming a polycrystal material which uses the amorphous silicon material in an incompletely molten state in the step region as a crystal nucleus.

6. The method according to claim 1, further comprises, prior to forming a pattern including an active layer on a base substrate, forming a buffer layer on the base substrate, the buffer layer being located between the base substrate and the active layer.

7. The method according to claim 1, further comprising forming a source/drain doped region in the active layer by ion injection.

8. The method according to claim 7, further comprises, prior to performing ion injection on the active layer,
forming a gate insulating layer on a substrate with the active layer;
forming a pattern including a gate on a substrate with the gate insulating layer.

9. The method according to claim 8, further comprising:
irradiating the active layer with laser light from a side of the base substrate facing away from the active layer to activate ions of the source/drain doped region.

10. The method according to claim 7, further comprising:
irradiating the active layer with laser light to activate ions of the source/drain doped region;
forming a gate insulating layer over the active layer;
forming a gate over the gate insulating layer.

11. The method according to claim 9, wherein the laser light is excimer laser light.

12. The method according to claim 9, further comprising:
forming a passivation layer over the gate, and a first via hole and a second via hole penetrating through the gate insulating layer and the passivation layer;
forming a source and a drain over the passivation layer, wherein the source is electrically connected to the active layer via the first via hole, and the drain is electrically connected to the active layer via the second via hole;
forming a planarization layer over the source and the drain, and a third via hole penetrating through the planarization layer;
forming a pixel electrode over the planarization layer and electrically connecting the pixel electrode to the drain via the third via hole.

13. The method according to claim 12, further comprising forming an alignment film layer over the pixel electrode.

14. The method according to claim 1, wherein a difference in thickness between the step region of the active layer and other regions of the active layer is 300 to 500 Å.

15. A display substrate manufactured by a method comprising:
forming a pattern including an active layer on a base substrate using an amorphous silicon material, the active layer including at least one step region having a film thickness greater than a film thickness of other regions of the active layer;
crystallizing the amorphous silicon material in the active layer into a polysilicon material.

16. A display device comprising the display substrate according to claim 15.

17. The method according to claim 10, wherein the laser light is excimer laser light.

18. The method according to claim 10, further comprising:
forming a passivation layer over the gate, and a first via hole and a second via hole penetrating through the gate insulating layer and the passivation layer;
forming a source and a drain over the passivation layer, wherein the source is electrically connected to the active layer via the first via hole, and the drain is electrically connected to the active layer via the second via hole;
forming a planarization layer over the source and the drain, and a third via hole penetrating through the planarization layer;
forming a pixel electrode over the planarization layer and electrically connecting the pixel electrode to the drain via the third via hole.

19. The display substrate according to claim 15, wherein forming a pattern including an active layer on a base substrate using an amorphous silicon material, the active layer including at least one step region, comprises:
forming an amorphous silicon material layer on the base substrate;
removing hydrogen from the amorphous silicon material using annealing process;
forming a pattern including an active layer on the base substrate using a halftone mask, the active layer including a plurality of regularly arranged step regions.

20. The display substrate according to claim 15, wherein crystallizing the amorphous silicon material in the active layer into a polysilicon material comprises:
irradiating the active layer with laser light to crystallize the amorphous silicon material in the active layer into a polysilicon material.
